(19) United States
(12) Patent Application Publication
(10) Pub. No.: US 2004/0238119 A1
(43) Pub. Date: Dec. 2, 2004

(54) [APPARATUS AND METHOD FOR ETCHING SILICON NITRIDE THIN FILM ]

(76) Inventor: Ching-Yu Chang, Yilan Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,992

(22) Filed: May 26, 2003

(51) Int. Cl. H01L 21/306

(52) U.S. Cl. 156/345.11

(57) ABSTRACT

An apparatus and a method for etching a silicon nitride thin film are described. The method provides a phosphoric acid tank. A sonic wave generator is disposed on a side of the phosphoric acid tank. Thereafter, a wafer is submerged in the phosphoric acid tank, wherein a silicon nitride thin film is already formed on the wafer. The sonic wave generator is then turned on to conduct the etching or the removal of the silicon nitride thin film on the wafer. Since a sonic wave generator is installed on a side of the phosphoric acid tank, the mixing between water and the concentrated phosphoric acid in the phosphoric acid tank is more even to improve the etching uniformity of the thin film.

### BACKGROUND OF INVENTION

1. Field of Invention

The present invention relates to an apparatus and a method for etching. More particularly, the present invention relates to an apparatus and a method for etching a silicon nitride thin film.

2. Description of Related Art

In semiconductor processing, an etching process is used to remove a thin film that is not covered by a photoresist layer or a mask layer by way of chemical reaction or physical phenomenon to transfer a pattern from a photomask to the thin film. The post-etched thin film then serves as a part of the semiconductor device. In semiconductor processing, a complete removal of a thin film is often accomplished by an etching process. The current etching techniques in semiconductor processing are basically divided into wet etching and dry etching, wherein wet etching mainly relies on chemical reaction to perform the etching of the thin film.

A silicon nitride thin film is an insulation material that is typically etched or removed by a wet etching method. Presently, a silicon nitride thin film is etched using a phosphorous acid etching method. In other words, the etching of a silicon nitride thin film is conducted by submerging a wafer in a phosphoric acid tank to generate a chemical reaction between the silicon nitride thin film and water in order to etch or remove the silicon nitride thin film. The phosphoric acid solution in the phosphoric acid tank mainly serves as a catalyst.

The phosphoric acid solution in the phosphoric acid tank, however, is very concentrated. Water that is being delivered into the tank does not easily evenly mixed with the phosphoric acid solution. Further, if water that is being delivered into the tank is not well controlled, the condition of boiling bubble easily occurs, leading to wafer jump or tilt inside the phosphoric acid tank. Further, since the concentrated phosphoric acid solution and water can not be mixed easily, the problem of nonuniform etching may occur. From a microscopic point of view, having water droplets adsorbed on the wafer surface, the etching rate is higher at an area where the surface of the wafer is in contact with the water droplets than at an area of the wafer surface where there is no contact with the water droplets. A nonuniform etching rate is thereby resulted. More seriously, defects, such as, the generation of pits on the surface of a silicon wafer surface at the areas where water droplets adsorption occurs when the pad oxide layer is too thin or the silicon nitride thin film is over etched.

Conventionally, a method to improve the mixing of phosphoric acid and water in the phosphoric acid tank is to install a sieve plate at the bottom of and inside the phosphoric acid tank, wherein the sieve plate comprises a plurality of micropores. When water is being delivered to the tank, water must pass through the micropores before reaching the wafer. This method can improve the degree of even mixing between water and the phosphoric acid solution. However, such a method to improve the mixing between the phosphoric acid solution and water is limited and can not completely resolve the problem of uneven mixing.

### SUMMARY OF INVENTION

Accordingly, the present invention provides an apparatus and a method for etching a silicon nitride thin film, wherein the problem of uneven mixing during the etching of the silicon nitride thin film is resolved.

The present invention further provides an apparatus and a method for etching a silicon nitride thin film, wherein the condition of boiling bubble, leading to wafer jump and tilt during the etching of the silicon thin film is prevented.

The present invention provides an apparatus and a method for etching a silicon nitride thin film, wherein the apparatus comprises a phosphoric acid tank, a water unit, a piping system, a heating device, a sonic wave generator and a pressure pump. The phosphoric acid tank is connected to the water unit through the piping system, the water unit is also connected to a pressure pump. The one end of the piping system is connected to the bottom of the phosphoric acid tank to allow the delivery of a fixed amount of water at a time interval. Further, by disposing the heating device at the bottom of the phosphoric acid tank, the phosphoric acid tank is maintained at a fixed temperature. Further, the sieve plate is placed at the bottom of the phosphoric acid tank, and the sieve plate comprises a plurality of micropores. As a result, when water is delivered to the phosphoric acid tank from the water unit, water must pass through the micropores before reaching the wafer. The micropores on the sieve plate can further reduce the size of the water droplets that pass through the sieve plate. In addition, a sonic wave generator is disposed on two opposite sides of the phosphoric acid tank to provide a sonic wave to the phosphoric acid tank during an etching process to further reduce the size of the water droplets inside the phosphoric acid tank. Adsorption of the water droplets on the wafer surface is mitigated, and the rate of water dissolution in the phosphoric acid solution is enhanced.

The present invention further provides an etching method for a silicon nitride thin film, wherein the method comprises providing a phosphoric acid tank and a water unit. The phosphoric acid tank is connected to the water unit through the piping system, while the water unit is connected to a pressure pump. The one end of the piping system is connected to the bottom of the phosphoric acid tank in order to have a fixed amount of water delivered to the phosphoric acid tank at a time interval. A sonic generator is also installed on one side of the phosphoric acid tank. Thereafter, a wafer is submerged inside the phosphoric acid tank, wherein the wafer comprises a thin silicon nitride film already formed thereon. The sonic wave generator is turned on to conduct the etching of the silicon nitride thin film.

In accordance to the present invention, a sonic wave generator is installed on one side of the phosphoric acid tank. The sonic wave generated by the sonic wave generator can further reduce the size of the water droplets in the phosphoric acid tank during the etching of the silicon nitride thin film to provide an even mixing between the phosphoric acid solution and water.

Since the sonic wave generated by the sonic wave generator can further reduce the size of the water droplets in the phosphoric acid tank, the mixing between water and the phosphoric acid solution is more even. The condition of boiling bubble is thus prevented. The problem of wafer jump or tilt during an etching process can also be obviated.

Further, the sonic wave generated by the sonic wave generator not only enhances the dissolution rate of water in the phosphoric acid solution, water droplets are also less likely to adsorb on the wafer surface. The etching of a silicon nitride thin film is more uniform in accordance of the present invention.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram illustrating an apparatus for etching a silicon nitride thin film according to an embodiment of the present invention.

FIG. 2 is a top view of a sieve plate.

FIG. 3 is a diagram illustrating the relationship between temperature and time, which is based upon by the water unit for the delivery of water to the phosphoric acid tank.

### DETAILED DESCRIPTION

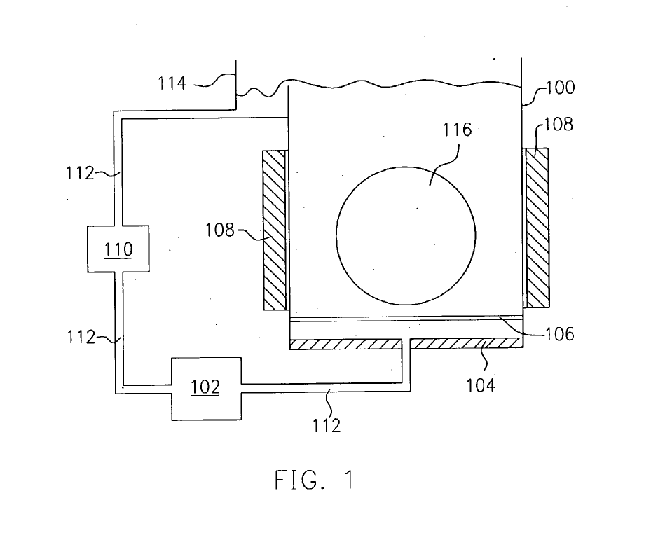

Referring to FIG. 1, FIG. 1 is a schematic diagram illustrating an apparatus for etching a silicon nitride thin film according to the embodiment of the present invention. The apparatus comprises a phosphoric acid tank 100, a water unit 102, a piping system 112, a heating device 104, a sonic wave generator 108 and a sieve plate 106.

The phosphoric acid tank 100 is filled with a concentrated phosphoric acid solution. The concentrated phosphoric acid is, for example, the commercially available 86% concentrated phosphoric acid solution. The phosphoric acid tank 100 is connected to the water unit 102 through the piping system 112, and the water unit 102 is further connected to a pressure pump 110. The one end of the piping system is connected to the bottom of the phosphoric acid tank 100 to allow the water unit 102 to deliver a fixed amount of water to the bottom of the phosphoric acid tank 100 at a time interval.

In one embodiment of the present invention, the phosphoric acid tank is, for example, an overflow tank, wherein the phosphoric acid solution is spilled over from the overflow tank into a collection tank 114. Through the piping system 112 and the pressure pump 110, the phosphoric acid solution in the collection tank 114 is further being delivered and recycled to the phosphoric acid tank.

Moreover, a heating device 104 is disposed at the bottom of the phosphoric acid tank 100 in order for the phosphoric acid tank 100 to maintain at a fixed temperature. Inone embodiment of the present invention, the heating device 104 is, for example, a hot plate. Further, the hot plate 104 allows the temperature of the phosphoric acid tank to maintain a temperature at about 160 degrees Celsius.

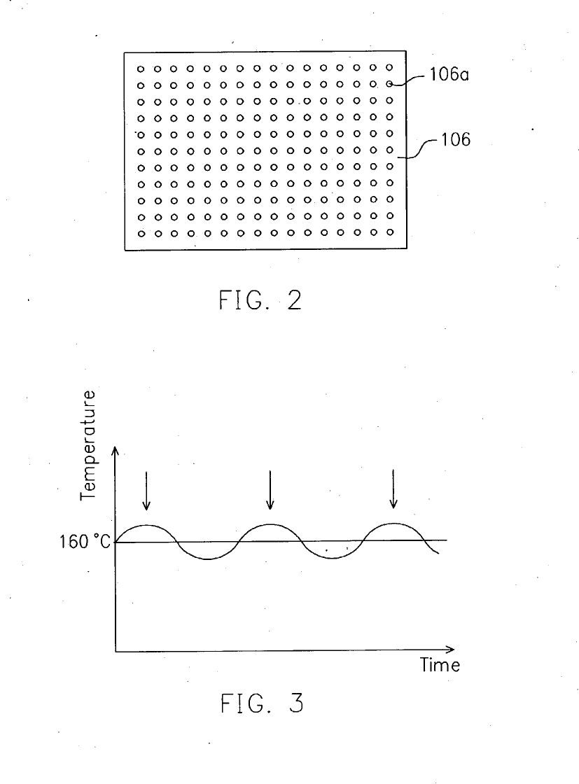

Further, the sieve plate 106 is disposed at the bottom of and inside the phosphoric acid tank 100, wherein the sieve plate 106 comprises a plurality of micropores 106a as shown in FIG. 2. Disposing the sieve plate 106 at the bottom of the phosphoric acid tank 100 allows water to pass through the micropores 106a on the sieve plate 106 before reaching the wafer 116 after water is delivered to the phosphoric acid tank 100 from the bottom of the phosphoric acid tank 100. Since the micropores 106a on the sieve plate 106 reduce the size of the water droplets, the provision of the sieve plate 106 prevents the development of bubble boiling because the size of the water droplets in the phosphoric acid tank is reduced.

In addition, a sonic wave generator 108 is disposed on a side of the phosphoric acid tank 100. The sonic wave generator 108 is, for example, a megasonic generator, which is disposed on two opposite sides of the phosphoric acid tank 100. The sonic wave generator 100 is used to provide a sonic wave to the phosphoric acid tank 100 during an etching process in order to reduce further the size of water droplets in the phosphoric acid tank 100. The condition of bubble boiling is effectively avoided. Further the sonic wave that is provided by the sonic wave generator reduces the tendency of water droplets to be adsorbed on the wafer 116 surface. The rate of water dissolving in the phosphoric acid solution is increased.

Accordingly, a method for etching a silicon nitride thin film is conducted using the aforementioned apparatus. The wafer 116 is placed in the aforementioned phosphoric acid tank, allowing the wafer 116 to soak in a phosphoric acid solution, wherein a silicon nitride thin film is already formed on the wafer 116.

Concurrently, a fixed amount of water is delivered to the phosphoric acid tank 100 at a fixed time through the piping system 112 from the water unit 102. In one embodiment of the present invention, the method for delivering water at a time interval by the water unit is shown in FIG. 3.

The y-axis in FIG. 3 represents the temperature of the phosphoric acid tank, while the x-axis in FIG. 3 represents the time. In general, the temperature inside a phosphoric acid tank 100 would display a regular cyclic variation. When the temperature reaches a certain high temperature (for example, at the time point indicated by the arrow), a fixed amount of water is delivered to the phosphoric acid tank.

Since etching or removing the silicon nitride thin film is achieved by generating a chemical reaction between the silicon nitride thin film and water, the phosphoric acid solution mainly plays the role of a catalyst and not an etching reactant. In other words, the size of the water droplets in the phosphoric acid tank and an uniform size distribution of the water droplets together affect the uniformity of the etching.

When the etching is being conducted, the sonic wave generator 108 is concurrently being activated to etch or remove the silicon nitride thin film on the wafer 100. In one embodiment, the sonic wave power generated by the sonic wave generator 108 is between, for example, 600 W to 1000 W. The sonic wave generated by the sonic wave generator further reduces the size of the water droplets in the phosphoric acid tank 100. The size of the water droplets is thereby more uniform. Beside, the sonic wave generated by the sonic wave generator 108 increases the rate of water dissolution in the phosphoric acid solution. The etching reaction rate is thus increased to prevent the condition of boiling bubble more effectively.

It is worth noting that, from a microscopic point of view, the etching rate is higher at an area where the surface of the wafer 116 is in contact with the water droplets than at an area of the wafer 116 surface where there is no contact with the water droplets. As a result, the etching is not uniform. More seriously, defects, such as, the generation of pits on the surface of a silicon wafer surface at the areas where the adhesion of the water droplets occurs when the pad oxide layer is too thin or the silicon nitride thin film is over etched. In accordance to the present invention, using a sonic wave generator to deliver a sonic wave in a phosphoric acid tank 100 increases the dissolution rate of water in the phosphoric acid solution. Beside reducing the size of the water droplets, the tendency of the water droplets to be adsorbed on the wafer 116 surface is reduced. As a result, the method for etching a silicon nitride thin film of the present invention resolves the non-uniformity problem in etching.

In accordance to the present invention, with the installation of a sonic generator on a side of the phosphoric acid tank, the size of the water droplets in the phosphoric acid tank is reduced by the sonic wave generated by the sonic generator. The mixing between the phosphoric acid solution and water is more even.

Since the sonic wave can reduce the size of the water droplets in the phosphoric acid tank and enhance an even mixing between the phosphoric acid and water, the condition of boiling bubble is prevented according to the present invention. As a result, wafer jump or tilt is also prevented in the wafer etching process.

The sonic wave generated by the sonic wave generator of the present invention not only increases the rate of water dissolution in the phosphoric acid solution, the tendency of water droplets to be adsorbed on the wafer surface is also reduced to improve the etching uniformity of a silicon nitride thin film.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An apparatus for etching a silicon nitride thin film, comprising:
a phosphoric acid tank;
a water unit;
a piping system, disposed between the phosphoric acid tank and the water unit;
a heating device, disposed at a bottom of the phosphoric acid tank; and
a sonic wave generator, disposed on an exterior side of the phosphoric acid tank.

2. The apparatus of claim 1, wherein a sieve plate is disposed at the bottom of and inside the phosphoric acid tank, wherein the sieve plate comprises a plurality of micropores.

3. The apparatus of claim 1, wherein the sonic wave generator is a megasonic generator.

4. The apparatus of claim 1, wherein the sonic wave generator is disposed on two opposite sides of the phosphoric acid tank.

5. The apparatus of claim 1, wherein the water unit is connected to a pressure pump.

6. A method for etching a silicon nitride thin film, comprising:
providing a phosphoric acid tank;
installing a sonic wave generator on a side of the phosphoric acid tank;
submerging a wafer in the phosphoric acid tank, wherein the wafer comprises a silicon nitride thin film formed thereon;
activating the sonic wave generator to enhance a mixing between a concentrated phosphoric acid solution and water; and
performing an etching on the silicon nitride thin film.

7. The method of claim 6, wherein a power of the sonic wave generated by the sonic wave generator is about 600 W to about 1000 W.

8. The method of claim 6, wherein water is delivered to a bottom of the phosphoric acid tank at a time interval.

9. The method of claim 6 further comprising a heating device to maintain the phosphoric acid tank at a fixed temperature.

10. A method for etching a silicon nitride thin film, comprising:
submerging a wafer in a phosphoric acid tank, wherein the wafer comprises a silicon nitride thin film formed thereon;
providing a sonic wave to the phosphoric acid tank to enhance a mixing between a concentrated phosphoric acid solution and water; and
perform an etching on the silicon nitride film.

11. The method of claim 10, wherein a power of the sonic wave is about 600 W to about 1000 W.

12. The method of claim 10, wherein water is delivered to a bottom of the phosphoric acid tank at a time interval.

13. The method of claim 10 further comprising using a heating device to maintain the phosphoric acid tank at a fixed temperature.
